(19) United States
(12) Patent Application Publication
(10) Pub. No.: US 2026/0372045 A1
(43) Pub. Date: Nov. 19, 2026

(54) SEMICONDUCTOR DEVICE

(71) Applicant: Samsung Electronics Co., Ltd., Suwon-si (KR)

(72) Inventors: Yanghee Lee, Suwon-si (KR); Myungseok Kim, Suwon-si (KR); Ilcheol Shin, Suwon-si (KR); Woohyuk Jang, Suwon-si (KR); Yukyung Seo, Suwon-si (KR)

(73) Assignee: Samsung Electronics Co., Ltd., Suwon-si (KR)

(21) Appl. No.: 19/400,242

(22) Filed: Nov. 25, 2025

(30) Foreign Application Priority Data
May 14, 2025 (KR) 10-2025-0062598

(51) Int. Cl. H10W 20/20; H10B 80/00; H10D 80/30; H10W 20/42; H10W 20/44; H10W 74/15; H10W 90/00; H10W 90/20; H10W 90/26

(52) U.S. Cl. CPC H10W 20/20; H10B 80/00; H10D 80/30; H10W 20/42; H10W 90/00; H10W 20/4405; H10W 20/4421; H10W 20/4441; H10W 74/15; H10W 90/26; H10W 90/297; H10W 90/722; H10W 90/732; H10W 90/792

(57) ABSTRACT

The present disclosure relates to a semiconductor device, and the semiconductor device comprises a substrate, a semiconductor element on the substrate, an insulating layer on the semiconductor element, a wiring structure on the insulating layer, the wiring structure comprising a first wiring and a second wiring, a contact plug passing through the insulating layer to connect the semiconductor element and the first wiring and a through via passing through the substrate and the insulating layer and connected to the second wiring, wherein an upper surface of the contact plug is located at a different level from an upper surface of the through via.

### CROSS-REFERENCE TO RELATED APPLICATIONS

This present application claims priority to and the benefit under 35 U.S.C. § 119(a)-(d) of Korean Patent Application No. 10-2025-0062598, filed with the Korean Patent Office on May 14, 2025, the entire disclosure of which is incorporated herein by reference.

### FIELD

The present disclosure relates to a semiconductor device.

### BACKGROUND

A semiconductor is a material that belongs to the intermediate region between conductors and insulators, and is a material that conducts electricity under certain conditions. Using these semiconductor materials, various semiconductor devices may be manufactured, such as memory devices. These semiconductor devices may be used in a variety of electronic devices.

As electronic devices become more miniaturized and highly integrated, there is a need to finely form the patterns that make up semiconductor elements. As the width of these micro-patterns gradually decreases, process difficulty increases and the defect rate of semiconductor devices may increase.

### SUMMARY

The embodiments are directed to providing a semiconductor device having improved reliability and preventing electrical short-circuiting between metals.

According to embodiments, a semiconductor device may comprise a substrate, a semiconductor element on the substrate, an insulating layer on the semiconductor element, a wiring structure on the insulating layer, the wiring structure comprising a first wiring and a second wiring, a contact plug passing through the insulating layer to connect the semiconductor element and the first wiring and a through via passing through the substrate and the insulating layer and connected to the second wiring, wherein an upper surface of the contact plug is located at a different level from a level of an upper surface of the through via.

According to embodiments, the semiconductor device may comprise a base die comprising a plurality of conductive lines, a plurality of memory dies stacked on the base die, and a molding material covering the base die and the plurality of memory dies, wherein each of the plurality of memory dies comprises a substrate, a semiconductor element on the substrate, an insulating layer on the semiconductor element, a wiring structure on the insulating layer, the wiring structure comprising a first wiring and a second wiring, a contact plug passing through the insulating layer to connect the semiconductor element and the first wiring and a through via passing through the substrate and the insulating layer and connected to the second wiring, wherein an upper surface of the contact plug is located at a different level from a level of an upper surface of the through via.

According to embodiments, the semiconductor device may comprise a base die, a memory stack on the base die and a molding material encapsulating the memory stack on the base die, wherein the memory stack comprises a plurality of memory dies and a plurality of interconnection structures, wherein the plurality of memory dies comprise a first memory die disposed closest to the base die and a second memory die disposed on the first memory die, wherein the plurality of interconnection structures comprise a first interconnection structure connecting the base die and the first memory die, and a second interconnection structure connecting the first memory die and the second memory die, wherein the first memory die and the second memory die each comprise a semiconductor element on a substrate, an insulating layer on the semiconductor element, a wiring structure on the insulating layer, the wiring structure comprising a first wiring and a second wiring, a contact plug passing through the insulating layer to connect the semiconductor element and the first wiring and a through via passing through the substrate and the insulating layer and connected to the second wiring, wherein an upper surface of the contact plug is located at a different level from a level of an upper surface of the through via.

### BRIEF DESCRIPTION OF THE DRAWINGS

FIG. 1 is a cross-sectional view illustrating a high bandwidth memory according to embodiments.

FIG. 2 is a cross-sectional diagram illustrating a high bandwidth memory according to some embodiments.

FIG. 3 is a plan view illustrating a semiconductor device according to embodiments.

FIG. 4 is a plan view illustrating a partial region of the semiconductor device according to embodiments.

FIG. 5 is a cross-sectional view taken along lines A-A′, B-B′, and C-C′ of FIG. 4.

FIG. 6 is a cross-sectional view illustrating a semiconductor device according to embodiments.

FIGS. 7 to 17 are cross-sectional views illustrating a portion of a manufacturing process of region M of FIG. 6 according to embodiments.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. To clearly represent the various layers and regions in the drawing, the thickness is enlarged and shown. And in the drawing, for convenience of explanation, the thickness of some layers and regions is exaggerated.

Additionally, when we say that a part, such as a layer, membrane, region, or plate, is “over” or “on” another part, this may comprise not only cases where it is “directly over” the other part, but also cases where there are other parts in between. Conversely, when we say that a part is “directly above” another part, we mean that there is no other part in between. Also, being “above” or “on” a reference part means being located above or below the reference part, and does not necessarily mean being located “above” or “on” the opposite direction of gravity.

Additionally, throughout the specification, whenever a part is said to “comprise” a component, this does not mean that it excludes other components, but rather that it may comprise other components, unless otherwise specifically stated.

Additionally, throughout the specification, when we say “in plan”, we mean when the target portion is viewed from above, and when we say “in cross section”, we mean when the target portion is viewed from the side in a cross-section cut vertically.

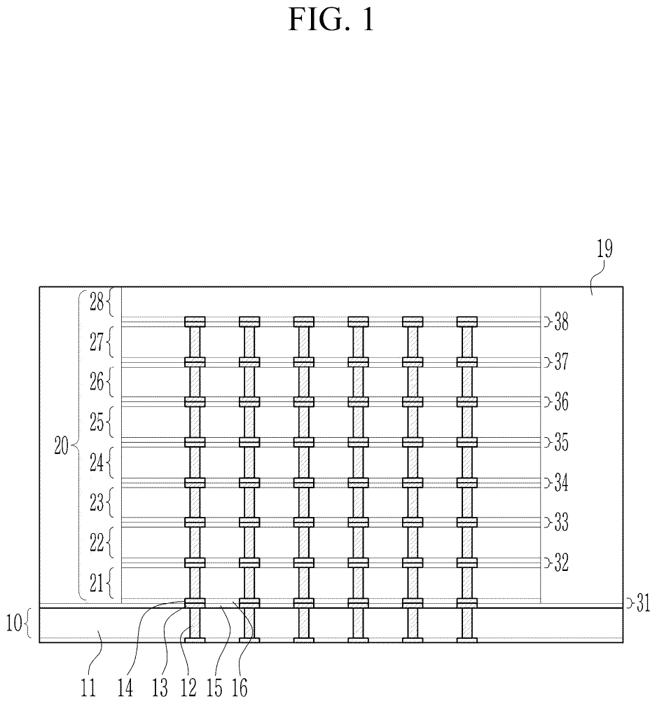

FIG. 1 is a cross-sectional view illustrating a high-bandwidth memory according to embodiments.

Referring to FIG. 1, a high bandwidth memory according to embodiments may comprise a base die 10, a first memory die 21 to an eighth memory die 28, and a molding material 19.

According to embodiments, the high bandwidth memory may comprise a memory stack 20 comprising a first memory die 21 to an eighth memory die 28. A memory stack 20 may mean a structure in which the plurality of memory dies are stacked. Although FIG. 1 illustrates eight memory dies being stacked, it is not limited thereto and the number of stacked memory dies may vary.

In this way, high bandwidth memory is formed by placing a memory stack 20 manufactured by stacking the plurality of memory dies on a base die 10. Therefore, as the number of memory dies comprised in the memory stack 20 increases, it is possible to implement a high-performance, high-bandwidth memory.

According to embodiments, the memory dies located at the bottom of the memory stack 20 to the memory dies located at the top may be sequentially defined as the first memory die 21 to the eighth memory die 28. For example, a second memory die 22 may be positioned on a first memory die 21, and a third memory die 23 may be positioned on the second memory die 22. A fourth memory die 24, a fifth memory die 25, a sixth memory die 26, a seventh memory die 27, and an eighth memory die 28 may be sequentially stacked on a third memory die 23.

In embodiments, the base die 10 may be located at the bottom of the high bandwidth memory and between the memory stack 20 and an external device (not shown). For example, the base die 10 may be a logic die.

According to embodiments, the base die 10 may temporarily store information transmitted and received between the memory stack 20 and an external device to prevent data loss that may occur when data is transmitted and received between the memory stack 20 and an external device (not shown) having different data processing speeds, processing units, and usage times.

According to embodiments, when the base die 10 transmits data to the memory stack 20 or receives data from the memory stack 20, it may arrange the order of the data and then transmit them sequentially. The base die 10 may comprise logic circuitry (not shown) for independently controlling the plurality of memory channels, through-silicon vias 12, and a die base 11.

In embodiments, the memory stack 20 may be located on the base die 10. The memory stack 20 may comprise a first memory die 21 to an eighth memory die 28. In embodiments, the memory stack 20 may be coupled to the base die 10 in a hybrid bonding manner. According to embodiments, the first memory die 21 to the eighth memory die 28 of the memory stack 20 may be coupled to one another in a hybrid bonding manner.

Hybrid bonding may be performed between the base die 10 and the memory stack 20, or between the first memory die 21 to the eighth memory die 28 constituting the memory stack 20, using the first interconnection structure 31 to the eighth interconnection structure 38. For example, a first interconnection structure 31 is positioned between the base die 10 and the first memory die 21, a second interconnection structure 32 is positioned between the first memory die 21 and the second memory die 22, a third interconnection structure 33 is positioned between the second memory die 22 and the third memory die 23, a fourth interconnection structure 34 is positioned between the third memory die 23 and the fourth memory die 24, a fifth interconnection structure 35 is positioned between the fourth memory die 24 and the fifth memory die 25, a sixth interconnection structure 36 is positioned between the fifth memory die 25 and the sixth memory die 26, a seventh interconnection structure 37 is positioned between the sixth memory die 26 and the seventh memory die 27, and a seventh interconnection structure 37 is positioned between the seventh memory die 27 and the eighth memory die 28. An 8th interconnection structure 38 may be located.

Hybrid bonding is achieved by fusing the same materials of two devices by taking advantage of the bonding properties between the same materials. Here, “hybrid” means a case where two different types of bonding methods are applied simultaneously, comprising, for example, joining two devices by simultaneously applying a first type of metal-to-metal bonding and a second type of non-metal-to-non-metal bonding. Hybrid bonding allows the implementation of fine-pitch I/O interfaces.

According to embodiments, each of the first interconnection structures 31 to the eighth interconnection structures 38 may comprise first bonding pads 13, second bonding pads 14, a first silicon insulating layer 15, and a second silicon insulating layer 16.

According to embodiments, the first bonding pads 13 may be located on the upper surface of the base die 10 and/or on the upper surface of each of the first to seventh memory dies 21 to 27. According to embodiments, the second bonding pads 14 may be located on the lower surface of each of the first memory die 21 to the eighth memory die 28. The first silicon insulating layer 15 may be positioned on the upper surface of the base die 10, or on the upper surface of each of the first to seventh memory dies 21 to 27. The second silicon insulating layer 16 may be positioned on the lower surface of each of the first to eighth memory dies 21 to 28.

According to embodiments, the first bonding pad 13 may be directly bonded to the second bonding pad 14 by metal-metal hybrid bonding. Metal bonding is formed at the interface between the first bonding pad 13 and the second bonding pad 14 by metal-metal hybrid bonding. According to embodiments, the first bonding pad 13 and the second bonding pad 14 may comprise copper. According to some embodiments, the first bonding pad 13 and the second bonding pad 14 may comprise a metal material capable of applying hybrid bonding.

According to embodiments, the first bonding pad 13 and the second bonding pad 14 are composed of the same material, so that after hybrid bonding, the interface between the first bonding pad 13 and the second bonding pad 14 may not be visible. The base die 10, the memory stack 20, and the first memory die 21 to the eighth memory die 28 may be electrically connected to one another through the first bonding pad 13 and the second bonding pad 14.

According to embodiments, the first silicon insulating layer 15 may be directly bonded to the second silicon insulating layer 16 by nonmetal-nonmetal hybrid bonding. A covalent bond is formed at the interface between the first silicon insulating layer 15 and the second silicon insulating layer 16 by nonmetal-nonmetal hybrid bonding. According to embodiments, the first silicon insulating layer 15 and the second silicon insulating layer 16 may comprise silicon oxide or Tetraethyl Orthosilicate (TEOS).

For example, the first silicon insulating layer 15 and the second silicon insulating layer 16 may comprise SiO₂, silicon nitride, silicon oxynitride, SiN, SiCN, or a combination thereof.

According to embodiments, the first silicon insulating layer 15 and the second silicon insulating layer 16 are composed of the same material, so that after hybrid bonding, the interface between the first silicon insulating layer 15 and the second silicon insulating layer 16 may not be visible.

According to embodiments, the first memory die 21 to the seventh memory die 27 may each have independently operable memory channels (not shown) comprising a plurality of input/output circuits and control circuits, and may comprise through-silicon vias 12 and a die base 11. The eighth memory die 28 may also have a memory channel (not shown) by comprising a plurality of input/output circuits and control circuits, and may comprise a die base 11.

According to embodiments, the first memory die 21 to the eighth memory die 28 may each be a DRAM. The number of stacked memory dies is not limited to that illustrated in FIG. 1, and high bandwidth memories comprising fewer or more memory dies may be comprised within the scope of the present disclosure.

In embodiments, for electrical coupling between the base die 10 and the first memory die 21 to the eighth memory die 28, the base die 10 and the first memory die 21 to the seventh memory die 27 may comprise through silicon vias 12. The eighth memory die 28, which is located at the very top, may not comprise through silicon vias 12. Through-silicon vias 12 may be formed by drilling thousands of microscopic holes vertically through each die and filling the holes with conductive material to connect them to electrodes.

According to embodiments, the hole of the through silicon via 12 may be formed by deep etching. According to some embodiments, the hole of the through silicon via 12 may be formed by a laser. In embodiments, the hole of the through silicon via 12 may be filled with a conductive material by electrolytic plating.

According to embodiments, the through silicon via 12 may comprise at least one of tungsten, aluminum, copper, and alloys thereof. Additionally, although not shown, a barrier layer (not shown) may be positioned between the insulating material of the base die 10 and the through silicon via 12. Likewise, a barrier layer (not shown) may be positioned between the insulating material and the through silicon via 12 of each of the first memory die 21 to the seventh memory die 27. For example, the barrier layer (not shown) may comprise at least one of titanium, tantalum, titanium nitride, tantalum nitride, or alloys thereof.

In embodiments, the molding material 19 is positioned on the base die 10 and may mold the memory stack 20. The molding material 19 serves to protect and insulate the memory stack 20. For example, the molding material 19 may be an epoxy molding compound (EMC).

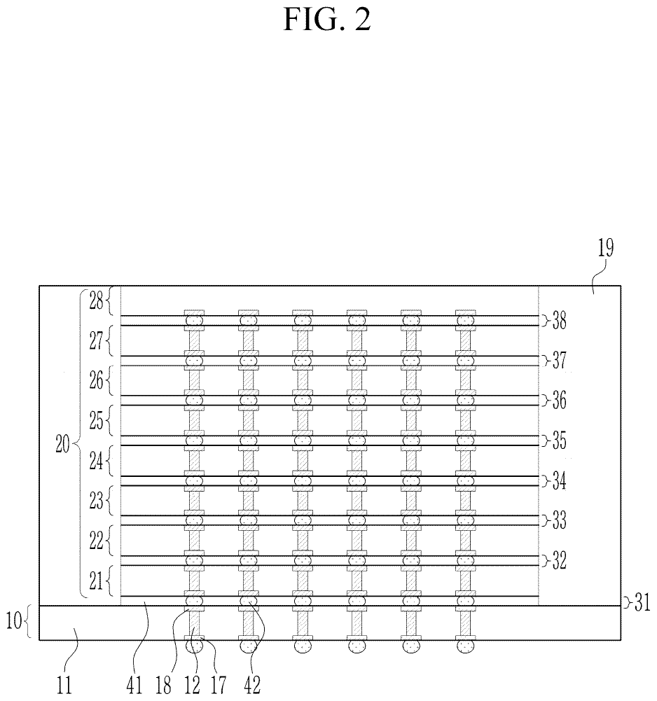

FIG. 2 is a cross-sectional diagram illustrating a high bandwidth memory according to some embodiments.

The high bandwidth memory illustrated in FIG. 2 may comprise components similar to or identical to the high bandwidth memory described with reference to FIG. 1. However, the high bandwidth memory in this embodiment is different from that illustrated in FIG. 1 in that each of the first to eighth interconnection structures 31 to 38 comprises an insulating member 41 and a connecting member 42. Here, any content that overlaps with that described above in FIG. 1 will be briefly explained or omitted, and the differences will be explained primarily.

Referring to FIG. 2, a high bandwidth memory according to embodiments may comprise a base die 10, a first memory die 21 to an eighth memory die 28, and a molding material 19.

According to embodiments, the base die 10 and the memory stack 20 may be coupled to one another by a first interconnection structure 31. Specifically, the base die 10 and the first memory die 21 located at the bottom of the memory stack 20 may be connected to one another by a first interconnection structure 31. According to embodiments, the first memory die 21 to the eighth memory die 28 may be coupled to one another by the second interconnection structure 32 to the eighth interconnection structure 38. Each of the first interconnection structure 31 to the eighth interconnection structure 38 may comprise insulating members 41 and connecting members 42.

In embodiments, the connecting member 42 may comprise micro bumps. An insulating member 41 may be positioned between the base die 10 and the first memory die 21 of the memory stack 20 to surround the connecting members 42. Likewise, an insulating member 41 may be positioned between the first memory die 21 to the eighth memory die 28 to surround the connecting members 42. The insulating member 41 may relieve stress between the base die 10 and the first memory die 21 of the memory stack 20, and between the first memory die 21 to the eighth memory die 28. For example, the insulating member (41) may comprise a non-conductive film (NCF).

According to embodiments, the base die 10 may comprise logic circuitry (not shown) for independently controlling the plurality of memory channels, first connection pads 17, through-silicon vias 12, second connection pads 18, and a die base 11. According to embodiments, the first memory die 21 to the seventh memory die 27 may each comprise independently operable memory channels (not shown), first connection pads 17, through-silicon vias 12, second connection pads 18, and a die base 11, each comprising a plurality of input/output circuits and control circuits. The eighth memory die 28 may comprise independently operable memory channels (not shown), first connection pads 17, and a die base 11 comprising a plurality of input/output circuits and control circuits.

In embodiments, the first connection pad 17 may be located between the connection member 42 and the through silicon via 12. The first connection pad 17 may electrically connect the through silicon via 12 to the connection member 42. A through silicon via 12 may be located between the first connection pad 17 and the second connection pad 18. A through silicon via 12 may electrically connect the second connection pad 18 to the first connection pad 17. The second connection pad 18 may be located between the through silicon via 12 and the connection member 42. The second connection pad 18 may electrically connect the connection member 42 to the through-silicon via 12.

In FIG. 2, other configurations than the first interconnection structure 31 to the eighth interconnection structure 38 are the same as those described in FIG. 1. Therefore, the contents described in FIG. 1 may be equally applied to other configurations other than the first interconnection structure 31 to the eighth interconnection structure 38 in FIG. 2.

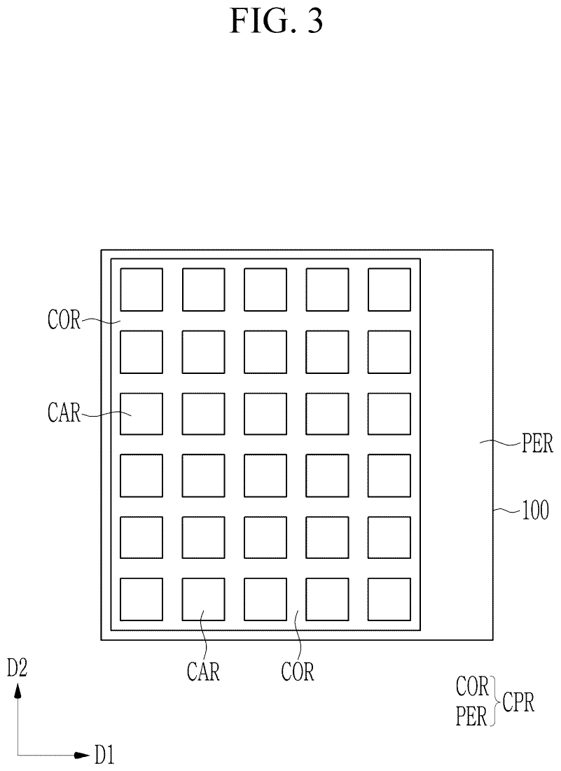

Hereinafter, with reference to FIGS. 3 to 5, a description will be given of one of the semiconductor devices comprised in each of the plurality of memory dies of the high bandwidth memory illustrated in FIG. 1 or FIG. 2.

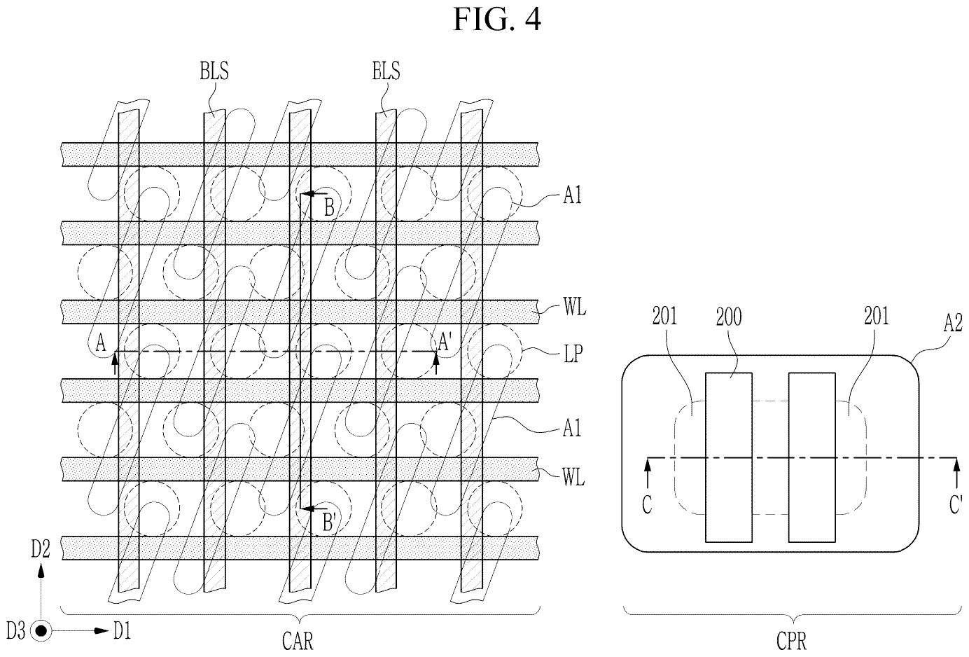

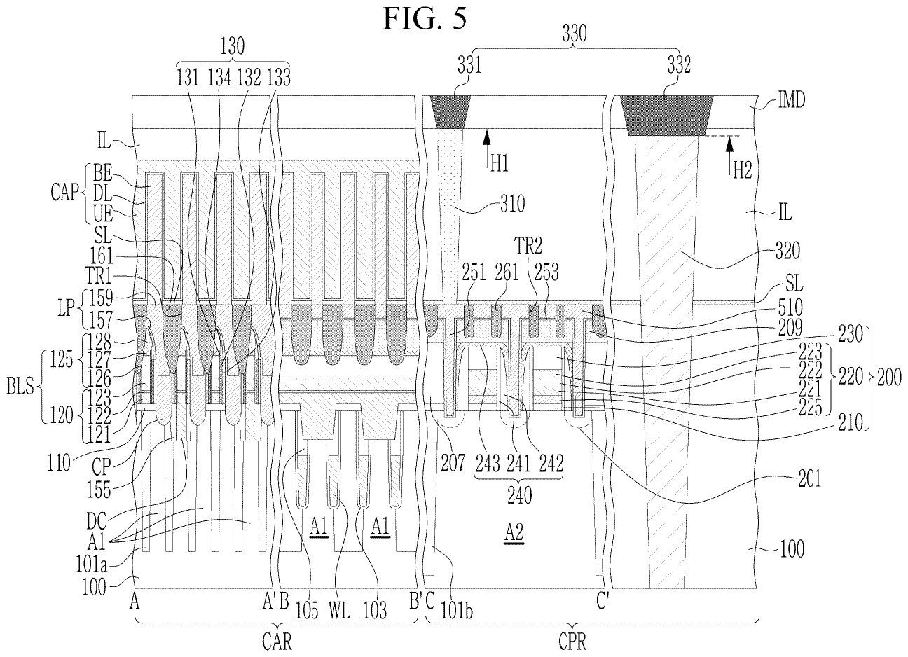

FIG. 3 is a plan view illustrating a semiconductor device according to embodiments. FIG. 4 is a plan view illustrating a partial region of a semiconductor device according to embodiments. FIG. 5 is a cross-sectional view taken along lines A-A′, B-B′, and C-C′ of FIG. 4.

As illustrated in FIG. 3, a semiconductor device according to embodiments may comprise a substrate 100 comprising a cell array region CAR and a core/periphery region CPR. The core/periphery region CPR may be located on the periphery of the cell array region CAR and may comprise a core region COR and a peripheral circuit region PER.

According to embodiments, the substrate 100 may comprise a plurality of cell array regions CAR, and the plurality of cell array regions CAR may be arranged in a matrix form along a first direction D1 and a second direction D2. The second direction D2 may intersect the first direction D1. The second direction D2 may intersect perpendicularly with the first direction D1. Each of the plurality of cell array regions CAR may have a rectangular shape comprising two sides parallel along the first direction D1 and two sides parallel along the second direction D2. The plurality of cell array regions CAR may be spaced apart from one another, and a core region COR may be located between the plurality of cell array regions CAR. Each cell array region CAR may be surrounded by a core region COR. The core region COR may have a mesh shape on the plane.

In embodiments, a peripheral circuit region PER may be located on one side of a plurality of cell array regions CAR and a core region COR. Although the plurality of cell array regions CAR and core regions COR are depicted as being located only on the left side of the peripheral circuit region PER, the plurality of cell array regions CAR and core regions COR may also be located on the right side of the peripheral circuit region PER. A plurality of cell array regions CAR may be gathered together to form a bank, and although not explicitly shown, a plurality of banks may be arranged along the second direction D2 on both sides of the peripheral circuit region PER.

The arrangement, shape, etc. of the cell array region CAR, core region COR, and peripheral circuit region PER have been described above, but this is only one example and is not limited thereto, and may be changed in various ways.

According to embodiments, a memory cell may be located in each of the plurality of cell array regions CAR. In each cell array region CAR, at least one of a memory cell of a volatile memory element and a memory cell of a non-volatile memory element may be located. For example, cell transistors such as dynamic random access memory (DRAM) and flash memory may be located in the cell array region CAR. Each cell array region CAR may have the plurality of unit memory cells positioned to store information. A unit memory cell may comprise at least one transistor and at least one capacitor.

According to embodiments, the core region COR and the peripheral circuit region PER may comprise driving circuits that generate signals capable of driving memory cells located in the cell array region CAR and wiring that transmits these signals. For example, the core region COR may contain a sense amplifier, a sub word line driver, etc. The peripheral circuit region PER may house a row decoder, a column decoder, etc.

A semiconductor device according to embodiments may comprise a transistor as a driving circuit for driving a memory cell. For example, a semiconductor device according to embodiments may comprise a PMOS transistor, an NMOS transistor, and the like. In this way, the transistors that make up the driving circuit may be located in the core/periphery region CPR.

Referring to FIGS. 4 and 5, a semiconductor device according to embodiments may comprise a substrate 100 comprising a cell array region CAR and a core/periphery region CPR.

According to embodiments, a first device isolation film 101a defining first active regions A1 may be disposed on a cell array region CAR of a substrate 100. The substrate 100 may be a semiconductor substrate comprising silicon, germanium or silicon-germanium.

According to embodiments, the first active regions A1 may be provided on an upper portion of the substrate 100. The first active regions A1 may be formed by patterning the upper portion of the substrate 100. The first active regions A1 may be two-dimensionally arranged along the first direction D1 and the second direction D2. The first active region A1 may have a rectangular shape (or bar shape). The first active region A1 may have a longitudinal axis in a diagonal direction with respect to the first direction D1 and the second direction D2. The width of the first active region A1 may decrease as it gets farther away from the bottom surface of the substrate 100 in the cross-section. For example, the first active region A1 may have a width that narrows from the bottom surface of the substrate 100 in a direction perpendicular to the top surface of the substrate 100 (e.g., in the third direction D3).

According to embodiments, word lines WL may be arranged within the substrate 100. The word lines WL may be arranged along the second direction D2. The word line WL may extend in a first direction D1 on a plane and cross the first active regions A1 and the first device isolation film 101a. A cell gate insulating film 103 may be interposed between the word lines WL and the substrate 100.

Specifically, gate recess regions may be formed within the first active regions A1 and the first element isolation film 101a. The cell gate insulating film 103 may conformally cover the inner walls of the gate recess regions. The word lines WL may be spaced apart from the first active regions A1 and the first element isolation film 101a with the cell gate insulating film 103 therebetween. The upper surfaces of the word lines WL may be located below the upper surface of the substrate 100. A gate capping layer 105 may be arranged on the upper surface of the word lines WL to fill the remainder of the gate recess regions. The level of the upper surface of the gate capping layer 105 may be substantially the same as the level of the upper surface of the substrate 100.

According to embodiments, the bit line structures BLS may extend in a second direction D2 across the first active regions A1 in the plane. Bit line structures BLS may intersect and be insulated from word lines WL. The bit line structures BLS may comprise a bit line 120 and a bit line capping pattern 125 on the bit line 120.

According to embodiments, the bit line 120 may comprise a polysilicon pattern 121, a silicide pattern 122, and a metal pattern 123 that are sequentially stacked. A lower insulating film 110 may be interposed between the polysilicon pattern 121 and the substrate 100. A bit line contact pattern DC may be located between the bit line 120 and the first active region A1. The bit line 120 may be electrically connected to the first active region A1 through a bit line contact pattern DC. The lower surface of the bit line contact pattern DC may be located below the upper surface of the substrate 100 and above the upper surfaces of the word lines WL. The bit line contact pattern DC may be formed within the substrate 100 and locally placed within a recessed region exposing the upper surface of the first active region A1. The recessed region may have an elliptical shape in a plane, and the width of the recessed region in the short axis direction may be greater than the width of the bit line structures BLS.

According to embodiments, a bit line capping pattern 125 may be disposed on a metal pattern 123 of a bit line 120. The bit line capping pattern 125 may comprise a first capping pattern 126, a second capping pattern 127, and a third capping pattern 128 that are sequentially stacked.

According to embodiments, a bit line contact spacer 155 may fill the remainder of the recessed region where the bit line contact pattern DC is formed. For example, the bit line contact spacer 155 may cover both sides of the bit line contact pattern DC. As another example, the bit line contact spacer 155 may surround the sides of the bit line contact pattern DC within the recessed area. The bit line contact spacer 155 may be formed of an insulating material having etch selectivity with respect to the lower insulating film 110. For example, the bit line contact spacer 155 may comprise a silicon oxide film, a silicon nitride film, and/or a silicon oxynitride film, and may be formed of a multilayer film. According to embodiments, the upper surface of the bit line contact spacer 155 may be positioned at substantially the same level as the upper surface of the lower insulating film 110.

In embodiments, storage contacts CP may be positioned between sidewalls of bit line structures BLS. Storage contacts CP may be arranged along a first direction D1 on the sidewalls of the bit line structures BLS. Each of the storage contacts CP may be arranged between word lines WL and between bit line structures BLS on a plane. Each of the storage contacts CP may be connected to the substrate 100 between two adjacent bit lines 120 among the bit lines 120. The storage contact CP may be electrically connected to the first active region A1 of the substrate 100. The storage contact CP may comprise, for example, doped polysilicon.

According to embodiments, the lower end of the storage contact CP may be located at a level lower than the upper surface of the substrate 100 and at a level higher than the lower end of the bit line contact pattern DC. The upper surface of the storage contact CP may be located below the lower surface of the bit line capping pattern 125 of the bit line structure BLS. The storage contact CP may be insulated from the bit line contact pattern DC by the bit line contact spacer 155.

In embodiments, a landing pad LP may be placed on a storage contact CP. The landing pad LP may be electrically connected to the first active region A1 of the substrate 100 through a storage contact CP. An upper surface of the landing pad LP may be located above the upper surfaces of the bit line structures BLS, and a lower surface of the landing pad LP may be located below the upper surfaces of the bit line structures BLS. For example, the lower surface of the landing pad LP may be positioned lower than the upper surface of the metal pattern 123 of the bit line 120. The landing pad LP may comprise a sequentially laminated barrier film 157 and a pad metal pattern 159. According to embodiments, a contact silicide pattern may be provided between a storage contact CP and a landing pad LP.

According to embodiments, a spacer structure 130 may be provided between the bit line structures BLS and the storage contacts CP. The spacer structure 130 may extend in the second direction D2 along the sidewalls of the bit line structures BLS. The spacer structure 130 may comprise a first spacer 131, a second spacer 132, a third spacer 133, and a fourth spacer 134. The first spacer 131 may be placed directly on the sidewall of the bit line structures BLS. The second spacer 132 may be placed between the first spacer 131 and the storage contact CP. A third spacer 133 may be placed between the second spacer 132 and the storage contact CP. The second spacer 132 may be positioned between the first spacer 131 and the third spacer 133. The first spacer 131 and the third spacer 133 may comprise an insulating material having etch selectivity with respect to the lower insulating film 110.

According to embodiments, the second spacer 132 may comprise an insulating material having a lower permittivity than the first spacer 131 and the third spacer 133. For example, the first spacer 131 and the third spacer 133 may comprise a silicon nitride film, and the second spacer 132 may comprise a silicon oxide film. As another example, the second spacer 132 may contain air. In other words, the second spacer 132 may be an air spacer defined between the side walls of the first spacer 131 and the third spacer 133. A fourth spacer 134 may be provided on the side surface of the first spacer 131 on the upper surface of the second spacer 132. The fourth spacer 134 may surround the lower portion of the landing pad LP. The fourth spacer 134 may have a ring shape on a plane.

In embodiments, an insulating pattern 161 may fill the space between landing pads LP. The insulating pattern 161 may surround the side walls of the landing pads LP. The insulating pattern 161 may be provided within a through via hole HL1 between the side walls of the landing pads LP, as illustrated in FIG. 5. The through via hole HL1 may be a node isolation hole that electrically isolates each of the landing pads LP. The landing pads LPs may be spaced apart from one another with a through via hole HL1 between them. The through via hole HL1 may have an inner surface defined by the surfaces of the landing pads LP, bit line capping patterns 125, and the spacer structure 130. For example, the insulating pattern 161 may comprise silicon nitride.

In embodiments, capacitors CAP may be provided on the landing pads LP. The capacitors CAP may be electrically connected to the landing pads LP, respectively. Each of the capacitors CAP may comprise a lower electrode BE, an upper electrode UE, and a dielectric layer DL therebetween. Each of the lower electrode BE and the upper electrode UE may comprise, for example, one of titanium, tantalum, tungsten, copper, and aluminum.

According to embodiments, the lower electrode BE and the upper electrode UE may each comprise doped silicon, Ru, RuO, Pt, PtO, Ir, IrO, SRO (SrRuO), BSRO ((Ba,Sr)RuO), CRO (CaRuO), BaRuO, La (Sr,Co)O, Ti, TiN, W, WN, Ta, TaN, TiAlN, TiSiN, TaAlN, TaSiN, or a combination thereof. The dielectric layer DL may comprise, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof.

According to embodiments, a gate stack 200 may be arranged on a substrate 100 in a core/periphery region CPR. The gate stack 200 may extend in a direction parallel to the upper surface of the substrate 100. For example, the gate stack 200 may have a bar shape on a plane. The gate stack 200 may be placed on a second active region A2 formed on an upper portion of the substrate 100. The second active region A2 may be a region doped with n-type or p-type impurities and may be defined by a second element isolation film 101b.

According to embodiments, impurity regions 201 may be formed on an upper portion of the substrate 100. The impurity regions 201 may comprise impurities of a different conductivity type from the impurities doped in the second active region A2. The impurity regions 201 may be a pair of source and drain regions that are electrically connected or separated depending on the voltage applied to the gate stack 200. The impurity regions 201 may be spaced apart from one another with the gate stack 200 between them. Each of the impurity regions 201 may be positioned adjacent to both sides of the gate stack 200. For example, the gate stack 200 and the impurity regions 201 may constitute a PMOS transistor, and the impurity regions 201 may be p-type impurity regions. The impurity regions 201 may comprise, for example, at least one of the elements boron (B), aluminum (Al), gallium (Ga), and indium (In). As another example, the gate stack 200 and the impurity regions 201 may constitute an NMOS transistor, and the impurity regions 201 may be n-type impurity regions. The impurity regions 201 may comprise, for example, at least one of the elements phosphorus (P), arsenic (As), and antimony (Sb).

According to embodiments, the gate stack 200 may comprise a gate insulating film 210, a gate electrode 220, and a gate capping pattern 230. A gate insulating film 210 may be interposed between the upper surface of the substrate 100 and the gate electrode 220. The gate capping pattern 230 may be placed on the upper surface of the gate electrode 220.

According to embodiments, the gate insulating film 210 may comprise a dielectric. According to embodiments, the gate insulating film 210 may comprise a first dielectric layer and a second dielectric layer on the first dielectric layer. The first dielectric layer may have a lower dielectric constant than the second dielectric layer. The first dielectric layer may comprise, for example, one of a silicon oxide film and a silicon oxynitride film. The second dielectric layer may comprise a high-k material having a higher dielectric constant than the silicon oxide film and/or the silicon oxynitride film. The second dielectric layer may comprise one of an oxide, nitride, silicide, or oxynitride, for example, comprising one of hafnium (Hf), aluminum (AI), zirconium (Zr), and lanthanum (La).

According to embodiments, the gate electrode 220 may comprise a work function control layer 225, a first conductive layer 221, a second conductive layer 222, and a third conductive layer 223 that are sequentially stacked. The work function control layer 225 may adjust the threshold voltage of the transistor. According to embodiments, the work function control layer 225 may have a thicker thickness than the gate insulating film 210. The work function control layer 225 may comprise at least one of a p-type metal film and an n-type metal film. The work function control layer 225 may comprise, for example, at least one of Ti, Ta, Al, Ni, Co, La, Pd, Nb, Mo, Hf, Ir, Ru, Pt, Yb, Dy, Er, Pd, TiAl, HfSiMo, TiN, WN, TaN, RuN, MoN, TiAlN, TaC, TiC, and TaC. The work function control layer 225 may further comprise, for example, at least one of La/TiN, Mg/TiN, or Sr/TiN.

According to embodiments, the first conductive layer 221 may comprise a doped semiconductor material. The first conductive layer 221 may comprise, for example, polysilicon. The first conductive layer 221 may be doped with, for example, a p-type dopant.

According to embodiments, the second conductive layer 222 may be positioned between the first conductive layer 221 and the third conductive layer 223. The second conductive layer 222 may have a thinner thickness than the first conductive layer 221 and the third conductive layer 223. The second conductive layer 222 may comprise silicide formed at the interface between the first conductive layer 221 and the third conductive layer 223. The second conductive layer 222 may comprise, for example, one of titanium silicide, cobalt silicide, nickel silicide, tungsten silicide, platinum silicide, and molybdenum silicide.

According to embodiments, the third conductive layer 223 may comprise a metallic material. The third conductive layer 223 may comprise, for example, at least one of W, Ti, or Ta.

According to embodiments, a gate capping pattern 230 may be disposed on an upper surface of the gate electrode 220. The gate capping pattern 230 is formed to cover the upper surface of the third conductive layer 223 to protect the gate electrode 220. The gate capping pattern 230 may comprise an insulating material. The gate capping pattern 230 may comprise, for example, silicon nitride.

In embodiments, a gate spacer structure 240 may be disposed on side surfaces of the gate stack 200. The gate spacer structure 240 may comprise a first gate spacer 241, a second gate spacer 242, and a third gate spacer 243.

According to embodiments, a first gate spacer 241 may be positioned on a side of the gate stack 200. The first gate spacer 241 may extend vertically along the side surfaces of the gate stack 200. The first gate spacer 241 may comprise a first dielectric layer of the gate insulating film 210 and a material having etch selectivity. The first gate spacer 241 may comprise, for example, silicon nitride. The upper surface of the first gate spacer 241 may be flush with the upper surface of the gate capping pattern 230, but is not limited thereto, and the gate capping pattern 230 may also cover the gate spacer 241. The first gate spacer 241 may be directly placed on the side of the gate electrode 220 and the side of the gate capping pattern 230.

According to embodiments, a second gate spacer 242 may be placed on the first gate spacer 241. The second gate spacer 242 may have a larger width than the first gate spacer 241. The width of the second gate spacer 242 may become smaller as it gets farther away from the upper surface of the substrate 100. The second gate spacer 242 may comprise, for example, silicon oxide.

According to embodiments, a third gate spacer 243 may be provided on the second gate spacer 242. The third gate spacer 243 may extend onto the upper surface of the gate stack 200 to cover the upper surface of the first gate spacer 241 and the upper surface of the gate capping pattern 230. The third gate spacer 243 may extend onto the upper surface of the substrate 100.

According to embodiments, a first interlayer insulating film 207 may be formed on a substrate 100. The first interlayer insulating film 207 may cover the sidewalls of the gate spacer structure 240 and may not cover the upper surface of the gate spacer structure 240. The upper surface of the first interlayer insulating film 207 may be coplanar with the upper surface of the third gate spacer 243. The first interlayer insulating film 207 may comprise an HDP oxide film or a silicon oxide film formed by a FCVD (flowable CVD) method. A second interlayer insulating film 209 may be positioned on the first interlayer insulating film 207. The lower surface of the second interlayer insulating film 209 may cover the upper surface of the third gate spacer 243. The second interlayer insulating film 209 may comprise silicon nitride.

In embodiments, the circuit wiring 510 may be positioned on the second interlayer insulating film 209. The circuit wiring 510 located in the core/periphery region CPR may be located in the same layer as the pad metal pattern 159 of the landing pad LP located in the cell array region CAR. The circuit wiring 510 may be formed in the same process using the same material as the pad metal pattern 159. Circuit wiring 510 may be connected to impurity regions 201 through contact vias 251. The contact via 251 and the circuit wiring 510 may comprise, for example, at least one of copper (Cu), tungsten (W), aluminum (Al), tantalum (Ta), and titanium (Ti). The contact via 251 may be connected to the substrate 100 by penetrating the first interlayer insulating film 207 and the second interlayer insulating film 209. According to embodiments, the lower end of the contact via 251 may be located at a level lower than the upper surface of the substrate 100. Contact vias 251 may electrically connect circuit wiring 510 and impurity regions 201.

According to embodiments, a contact barrier film 253 may cover the surfaces of the circuit wiring 510 and the contact via 251. A contact barrier film 253 may be provided between the lower surface of the circuit wiring 510 and the second interlayer insulating film 209. A contact barrier film 253 may be provided on the side surfaces and bottom surfaces of the contact via 251. The contact barrier film 253 may comprise a metal nitride. The contact barrier film 253 may comprise, for example, one of titanium nitride (TiN), tantalum nitride (TaN), and tungsten nitride (WN).

According to embodiments, a contact plug hole HL2 may be formed between the circuit wiring 510. A contact plug hole HL2 may be formed between the side walls of the circuit wiring 510 and may be formed to a predetermined depth from the upper surface of the second interlayer insulating film 209. The lower end of the contact plug hole HL2 may be located at a higher level than the upper surface of the gate capping pattern 230.

According to embodiments, the contact plug hole HL2 may be positioned to vertically overlap the gate stack 200 or to vertically overlap the second element isolation film 101b between the gate stacks 200.

According to embodiments, the wiring insulation pattern 261 may fill the contact plug hole HL2. For example, the wiring insulation pattern 261 may comprise silicon nitride.

According to embodiments, a lower etch-stop film SL covering the insulating pattern 161, the wiring insulating pattern 261, and the circuit wirings 510 may be provided. An insulating layer IL may be provided on the lower etch stop film SL. An insulating layer IL may be positioned over the cell array region CAR and core/periphery region CPR of the substrate 100. An insulating layer IL may cover capacitors CAP in the cell array region CAR. An insulating layer IL may cover the circuit wiring 510 in the core/periphery region CPR.

According to embodiments, a contact plug 310 may be provided that penetrates an insulating layer IL and a lower etch stop film SL and is connected to circuit wirings 510. The lower end of the contact plug 310 may come into contact with the upper surface of the circuit wiring 510. The lower surface of the contact plug 310 may come into contact with the upper surface of the circuit wiring 510.

According to embodiments, a signal wiring 330 may be positioned over the insulating layer IL. The signal wiring 330 may be located over the contact plug 310 and the through via 320. The signal wiring 330 may be spaced apart from the circuit wiring 510 in a direction perpendicular to the upper surface of the substrate 100. A plurality of signal wirings 330 may be spaced in a parallel direction on the upper surface of the substrate 100. For example, the signal wiring 330 may comprise a first signal wiring 331 connected to a contact plug 310 and a second signal wiring 332 connected to a through via 320.

According to embodiments, the contact plug 310 may connect between the circuit wiring 510 and the first signal wiring 331. The first signal wiring 331 may be electrically connected to the contact plug 310. The first signal wiring 331 may be electrically connected to the circuit wiring 510 through the contact plug 310. The circuit wiring 510 may receive a predetermined signal through the first signal wiring 331. For example, the contact plug 310 may comprise at least one of tungsten, copper, aluminum, tantalum, titanium, or a combination thereof.

In embodiments, the contact plug 310 may have a smaller horizontal width than the through via 320 described below. In other words, the contact plug 310 may have a first width in the horizontal direction, and the through via 320 may have a second width greater than the first width in the horizontal direction.

In embodiments, the through via 320 may be electrically connected to the second signal wiring 332. The through via 320 may have a structure that penetrates at least a portion of the insulating layer IL, the lower insulating film 110, and the substrate 100. The lower end of the through via 320 extends toward the lower surface of the substrate 100, and the upper end may penetrate at least a portion of the insulating layer IL and contact the lower surface of the second signal wiring 332.

According to embodiments, the through via 320 may be connected to a second signal wiring 332 to form an interface with the upper semiconductor chip. The second signal wiring 332 may transmit a signal from the outside to the internal circuit through a through via 320, or transmit a signal from the internal circuit to the outside.

Although not explicitly shown, the through via 320 may extend through the lower insulating film 110 and the substrate 100, and its sidewall may be surrounded by an insulating film in the region where it penetrates the substrate 100. For example, the sidewall of the through via 320 may be surrounded by a liner insulating film, and the interior may be filled with a conductive metal. For example, the conductive metal may comprise at least one of copper, tungsten, aluminum, or a combination thereof. Through vias 320 may be used as data input/output or power supply paths between semiconductor chips.

In embodiments, the upper surface of the contact plug 310 may be located at a different level than the upper surface of the through via 320. In embodiments, the upper surface of the contact plug 310 may be positioned at a higher level than the upper surface of the through via 320. Here, the level may be defined as a vertical distance from the upper surface of the substrate 100. In other words, the upper surface of the contact plug 310 may be located at a first level H1, and the upper surface of the through via 320 may be located at a second level H2 lower than the first level H1.

In embodiments, the height difference between the first level H1 and the second level H2 may be from about 10 Å to about 500 Å. Specifically, the height difference between the first level H1 and the second level H2 may be about 60 A to about 120 Å. More specifically, the height difference between the first level H1 and the second level H2 may be about 70 Å to about 100 Å.

In embodiments, an interconnect insulating layer IMD may be positioned over the insulating layer IL. An interconnect insulating layer IMD may cover the side of the signal wiring 330. An interconnect insulating layer IMD may be positioned between the plurality of signal wirings 330. For example, an interconnect insulating layer IMD may be positioned between the first signal wiring 331 and the second signal wiring 332. The first signal wiring 331 and the second signal wiring 332 may be insulated by a interconnect insulating layer IMD.

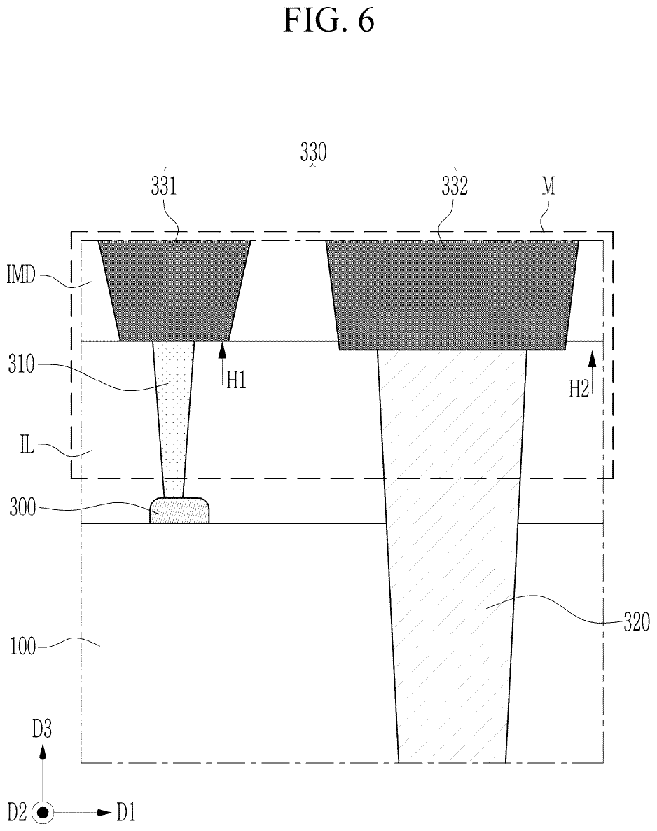

FIG. 6 is a cross-sectional view illustrating a semiconductor device according to embodiments.

Referring to FIG. 6, the semiconductor device may comprise a substrate 100, a semiconductor element 300 positioned on the substrate 100, an insulating layer IL covering the semiconductor element 300, a signal wiring 330 positioned on the insulating layer IL, a contact plug 310 connecting between the semiconductor element 300 and the signal wiring 330, and a through via 320 connected to the signal wiring 330.

According to embodiments, the substrate 100 may be a semiconductor substrate comprising silicon, germanium, or silicon-germanium, or a compound semiconductor substrate. According to embodiments, the substrate 100 may be an insulating substrate comprising an insulating material. The upper surface of the substrate 100 may be formed as a plane parallel to the first direction D1 and a second direction D2 intersecting the first direction D1.

According to embodiments, a semiconductor element 300 may be positioned on a substrate 100. Although only one semiconductor element 300 is illustrated in FIG. 6, this is only an example, and it is obvious that a plurality of semiconductor elements 300 may be comprised. Below, the concept comprising the plurality of semiconductor elements 300 is explained.

According to embodiments, at least some of the plurality of semiconductor elements 300 may be transistors. For example, at least some of the plurality of semiconductor elements 300 may be BJTs (Bipolar Junction Transistors) or FETs (Field Effect Transistors), and the FETs may have a planar transistor or FinFET (Fin Field Effect Transistor) structure.

According to embodiments, a plurality of semiconductor elements 300 may form a logic cell. A logic cell may contain various circuit elements such as transistors, resistors, capacitors, diodes, etc., and may be implemented as a circuit block that performs a specific logic function. For example, a logic cell may implement AND, NAND, OR, NOR, XOR(exclusive OR), XNOR(exclusive NOR), INV(inverter), BUF(buffer), DLY(delay), ADD(adder), FIL(filter), MUX, DEMUX, OAI(OR-AND-INVERT), AO(AND-OR), AOI(AND-OR-INVERT), D flip-flop, reset flip-flop, master-slave flip-flop, latch, etc. These logic cells are standard cells for performing various digital operations and may be used in circuit design such as central processing units CPU, graphics processing units GPU, and application processors AP.

According to embodiments, the plurality of semiconductor elements 300 may be devices for forming a memory cell. For example, the plurality of semiconductor elements 300 may be implemented as individual devices used to configure various nonvolatile and volatile memory devices such as DRAM, SRAM, flash memory, EEPROM, PRAM, MRAM, RRAM, etc.

In the case of a DRAM cell, some of the plurality of semiconductor elements 300 may be composed of an access transistor and a storage capacitor, and an SRAM cell may be composed of a cross-coupled inverter and an access transistor. Nonvolatile memory cells may comprise programmable resistors, magnetic layers, phase-change materials, transistors, etc.

Accordingly, a plurality of semiconductor elements 300 may be utilized as components of a semiconductor device that performs various functions such as logic operations, data storage, and processing.

According to embodiments, an insulating layer IL covering a semiconductor element 300 may be provided. An insulating layer IL may be positioned on the substrate 100.

According to embodiments, a signal wiring 330 may be positioned over the insulating layer IL.

In embodiments, the signal wiring 330 may be positioned over the contact plug 310 and the through via 320. The signal wiring 330 may be spaced apart from the semiconductor element 300 in a third direction D3. A plurality of signal wirings 330 may be spaced apart along the first direction D1. For example, the signal wiring 330 may comprise a first signal wiring 331 connected to a contact plug 310 and a second signal wiring 332 connected to a through via 320.

According to embodiments, the first signal wiring 331 may be electrically connected to the semiconductor element 300 through the contact plug 310. According to embodiments, the first signal wiring 331 may function as a path for transmitting a signal output from the semiconductor element 300 or transmitting a signal applied from the outside to the semiconductor element 300.

According to embodiments, the second signal wiring 332 may perform a function of transmitting a signal received from the outside to the internal circuit via the through via 320 or transmitting a signal generated from the internal circuit to the outside.

According to embodiments, the contact plug 310 may function as a conductive path that electrically connects between the semiconductor element 300 and the first signal wiring 331. The first signal wiring 331 is electrically connected to the contact plug 310 to enable signal transmission and reception with the semiconductor element 300. The first signal wiring 331 is electrically connected to the semiconductor element 300 via the contact plug 310, thereby being able to act as a passage for transmitting a signal output from the semiconductor element 300 to an external circuit or transmitting an input signal from an external circuit to the semiconductor element 300. Accordingly, the semiconductor element 300 may receive a predetermined control signal, clock signal, or data signal, etc., through the first signal wiring 331, or output it to an external circuit. For example, the contact plug 310 may comprise at least one of tungsten, copper, aluminum, tantalum, titanium, or a combination thereof.

In embodiments, the contact plug 310 may have a smaller horizontal width than the through via 320 described below. In other words, the contact plug 310 may have a first width in the horizontal direction, and the through via 320 may have a second width greater than the first width in the horizontal direction.

In embodiments, the through via 320 may be electrically connected to the second signal wiring 332. The through via 320 may have a structure that penetrates at least a portion of the insulating layer IL and the substrate 100. The lower end of the through via 320 extends toward the lower surface of the substrate 100, and the upper end may penetrate at least a portion of the insulating layer IL and contact the lower surface of the second signal wiring 332.

According to embodiments, the through via 320 may be connected to a second signal wiring 332 to form an interface with the upper semiconductor chip. The second signal wiring 332 may transmit a signal from the outside to the internal circuit through a through via 320, or transmit a signal from the internal circuit to the outside.

Although not explicitly shown, the through via 320 may extend through the substrate 100, and its sidewalls in the region where it penetrates the substrate 100 may be surrounded by an insulating film. For example, the sidewall of the through via 320 may be surrounded by a liner insulating film, and the interior may be filled with a conductive metal. For example, the conductive metal may comprise at least one of copper, tungsten, aluminum, or a combination thereof. Through vias 320 may be used as data input/output or power supply paths between semiconductor chips.

In embodiments, the upper surface of the contact plug 310 may be located at a different level than the upper surface of the through via 320. In embodiments, the upper surface of the contact plug 310 may be positioned at a higher level than the upper surface of the through via 320. Here, the level may be defined as a vertical distance from the upper surface of the substrate 100. In other words, the upper surface of the contact plug 310 may be located at a first level H1, and the upper surface of the through via 320 may be located at a second level H2 lower than the first level H1.

In embodiments, the height difference between the first level H1 and the second level H2 may be from about 10 Å to about 500 Å. Specifically, the height difference between the first level H1 and the second level H2 may be about 60 Å to about 120 Å. More specifically, the height difference between the first level H1 and the second level H2 may be about 70 Å to about 100 Å.

According to embodiments, the semiconductor device may further comprise an interconnect insulating layer IMD positioned over the insulating layer IL. An interconnect insulating layer IMD may cover the side of the signal wiring 330. An interconnect insulating layer IMD may be positioned between the plurality of signal wirings 330. For example, an interconnect insulating layer IMD may be positioned between the first signal wiring 331 and the second signal wiring 332. The first signal wiring 331 and the second signal wiring 332 may be insulated by a interconnect insulating layer IMD.

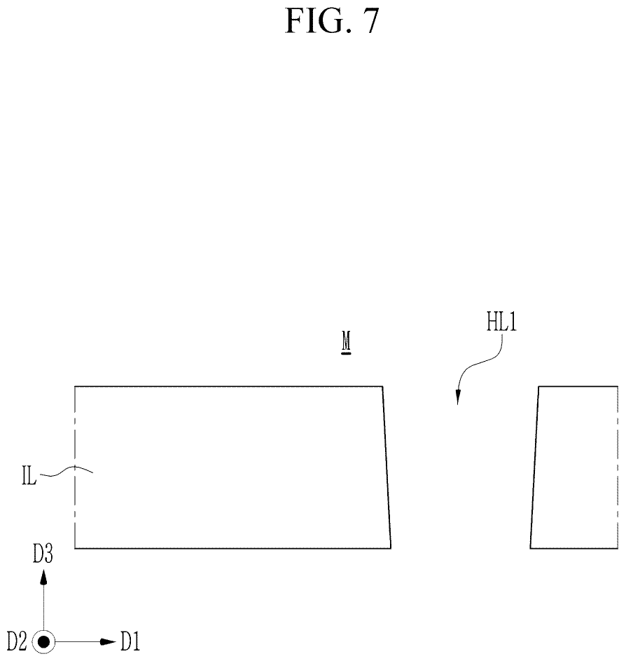

Hereinafter, a method for manufacturing a semiconductor device according to embodiments shown in FIG. 6 will be described with reference to FIGS. 7 to 17.

FIGS. 7 to 17 are cross-sectional views illustrating a portion of a manufacturing process of region M of FIG. 6 according to embodiments.

FIG. s 7 to 17 are cross-sectional views centered on a signal wiring 330, a contact plug 310 connected to the signal wiring 330, and a through via 320.

Referring to FIG. 7, an insulating layer IL may be formed on the substrate 100 illustrated in FIG. 6. An insulating layer IL may cover the semiconductor element 300 illustrated in FIG. 6.

In embodiments, the insulating layer IL may comprise an insulating material such as, but is not limited to, TEOS.

According to embodiments, a patterned mask layer (not shown) may be used as an etching mask to etch an insulating layer IL to form a contact plug hole HL2. Although not clearly shown in FIG. 7, the contact plug hole HL2 may penetrate the insulating layer IL and the substrate 100. In other words, the contact plug hole HL2 may extend along the third direction D3 from the upper surface of the insulating layer IL to the lower surface of the substrate 100. For example, the width of the through via hole HL1 may gradually decrease as it approaches the lower surface of the substrate 100. Afterwards, the hard mask layer (not shown) may be removed.

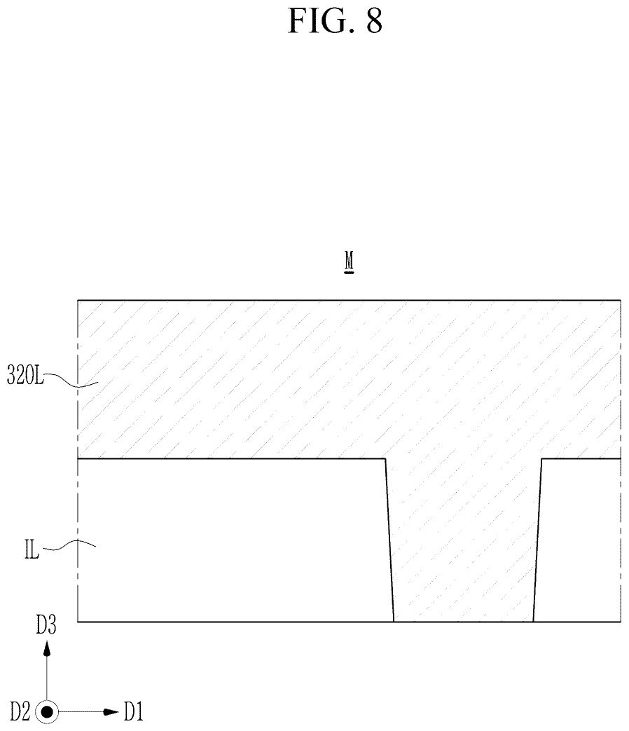

Referring to FIG. 8, a through via material layer 320L may be formed within a through via hole HL1 and on an insulating layer IL. The through via material layer 320L may fill the interior of the through via hole HL1. Although not explicitly shown, the through via material layer 320L may be formed, for example, by sequentially depositing a dielectric film and a barrier metal film, and then plating a conductive material within the through via hole HL1 to fill the interior of the through via hole HL1. The through via material layer 320L may cover the upper surface of the substrate 100 and the inner surface of the insulating layer IL within the through via hole HL1. The through via material layer 320L may cover the upper surface of the insulating layer IL.

For example, the conductive material may comprise, but is not limited to, at least one of copper, tungsten, aluminum, or combinations thereof.

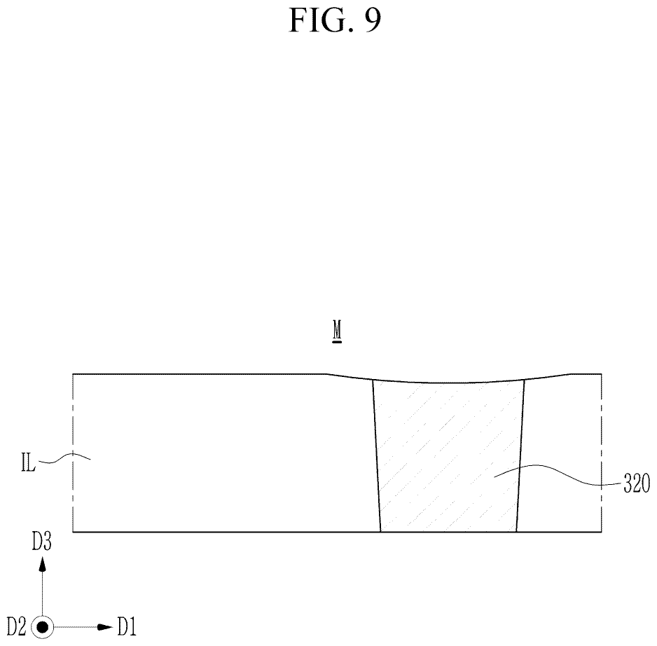

Referring to FIG. 9, a planarization process may be performed to form a through via 320. For example, the planarization process may comprise a chemical mechanical polishing (CMP) process.

A portion of the through via material layer 320L may be removed by the planarization process. The planarization process may proceed until the top surface of the insulating layer IL is exposed. However, the examples are not limited to this. The planarization process may be continued for a predetermined period of time after the upper surface of the insulating layer IL is exposed. In this case, the thickness of the insulating layer IL in the third direction D3 may be reduced after the planarization process.

During the planarization process, an region of the insulating layer IL adjacent to a through via hole (e.g., a through via hole HL1 in FIG. 7) may be removed more than an region of the insulating layer IL relatively far from the through via hole (e.g., a through via hole HL1 in FIG. 7). Accordingly, the upper surface of the through via 320 may be formed at a lower level than the upper surface of the insulating layer IL that is relatively far from the through via hole (e.g., the through via hole HL1 of FIG. 7).

Specifically, during the planarization process, more conductive materials (e.g., copper (Cu), tungsten (W), etc.) embedded in through via holes (e.g., through via holes HL1 in FIG. 7) may be removed due to differences in properties with the dielectric materials constituting the adjacent insulating layer IL. Accordingly, the upper surface of the through via 320 may be formed in a concave shape.

Additionally, the insulating layer IL may also be removed around the through via 320. This is due to the characteristics of the planarization process in which the polishing speed is relatively fast in regions with high metal density in a mixed structure of metal and insulator, and as a result, the insulating layer around the metal may be removed together.

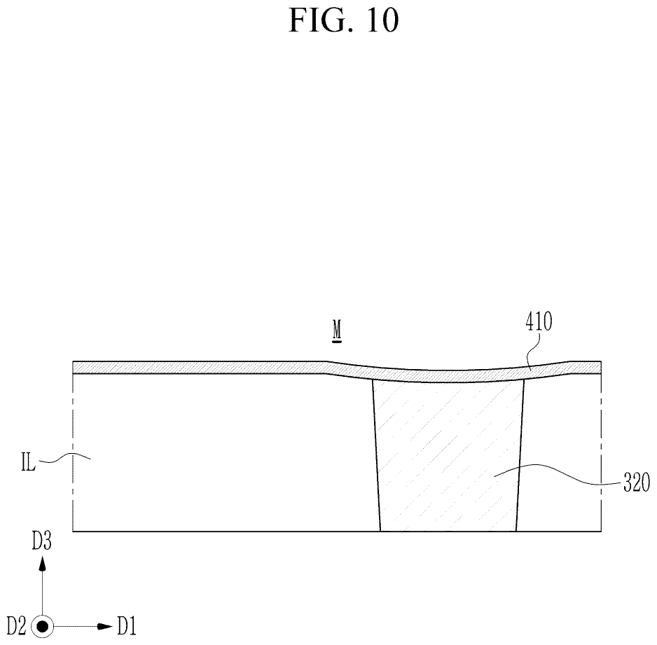

Referring to FIG. 10, a liner 410 may be formed over a through via 320 and an insulating layer IL.

In embodiments, the liner 410 may cover the upper surface of the through via 320 and the upper surface of the insulating layer IL. For example, the liner 410 may comprise an insulating material such as SiCN, SIN or SiON.

According to embodiments, since the upper surface of the through via 320 is formed at a lower level than the upper surface of the adjacent insulating layer IL, the liner 410 may be formed in a curved shape according to the concave region where the upper surface of the through via 320 is located. In other words, the liner 410 may extend relatively flatly on the upper surface of the insulating layer IL and may be formed along a rough shape by bending downward in the region where the through via 320 is located.

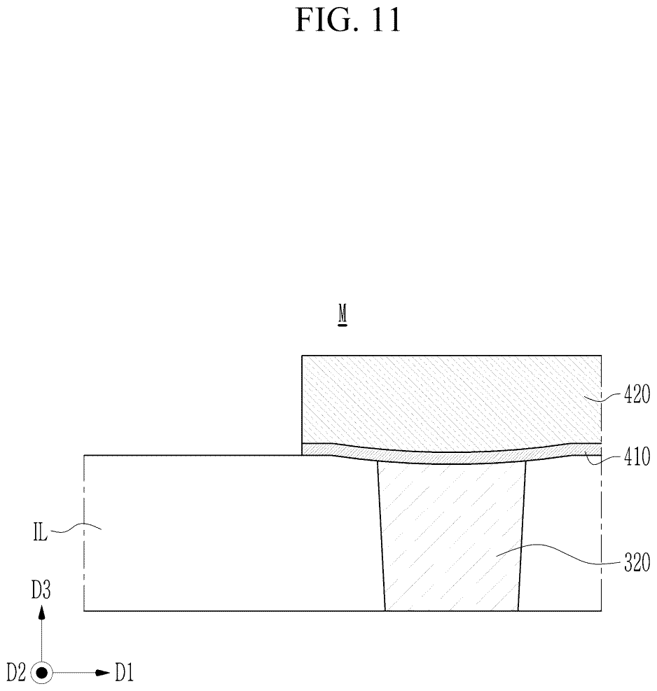

Referring to FIG. 11, a hard mask pattern 420 may be formed for selective removal of the liner 410.

According to embodiments, the hard mask pattern 420 may be formed on a liner 410 positioned over and adjacent to the through via 320. For example, a hard mask pattern 420 may be formed through a coating and patterning process.

In embodiments, the hard mask pattern 420 may be used as an etching mask to remove the exposed liner 410 through an etching process. At this time, the liner 410 of the region covered with the hard mask pattern 420 may remain, and the liner 410 of the exposed region may be removed.

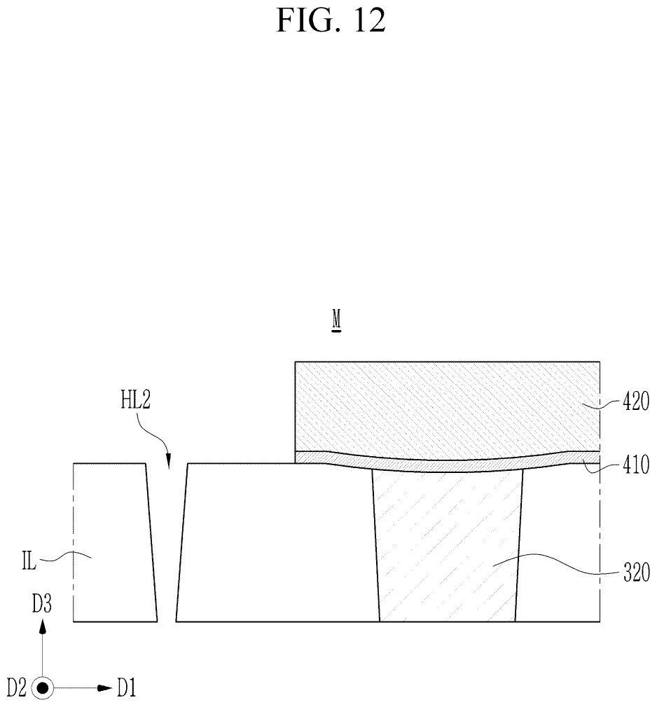

Referring to FIG. 12, a patterned mask layer (not shown) may be used as an etching mask to etch an insulating layer IL to form a contact plug hole HL2. Although not clearly shown in FIG. 12, the contact plug hole HL2 may extend along the third direction D3 from the upper surface of the insulating layer IL to the upper surface of the semiconductor element 300. The width of the contact plug hole HL2 may be smaller than the width of the through via hole HL1 described above. The width of the contact plug hole HL2 may gradually decrease as it approaches the lower surface of the substrate 100. Afterwards, the hard mask layer (not shown) may be removed.

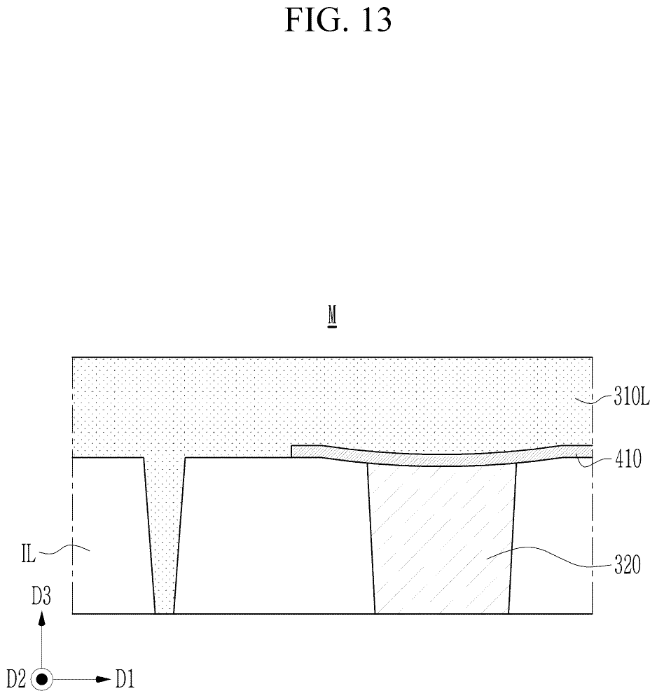

Referring to FIG. 13, a contact plug material layer 310L may be formed on the insulating layer IL and the liner 410 within the contact plug hole HL2 using a deposition process. The contact plug material layer 310L may fill the interior of the contact plug hole HL2. The contact plug material layer 310L may cover the upper surface of the semiconductor element 300 and the inner surface of the insulating layer IL within the contact plug hole HL2. The contact plug material layer 310L may cover the upper surface of the insulating layer IL and the liner 410.

For example, the contact plug material layer 310L may comprise, but is not limited to, at least one of tungsten, copper, aluminum, tantalum, titanium, or a combination thereof.

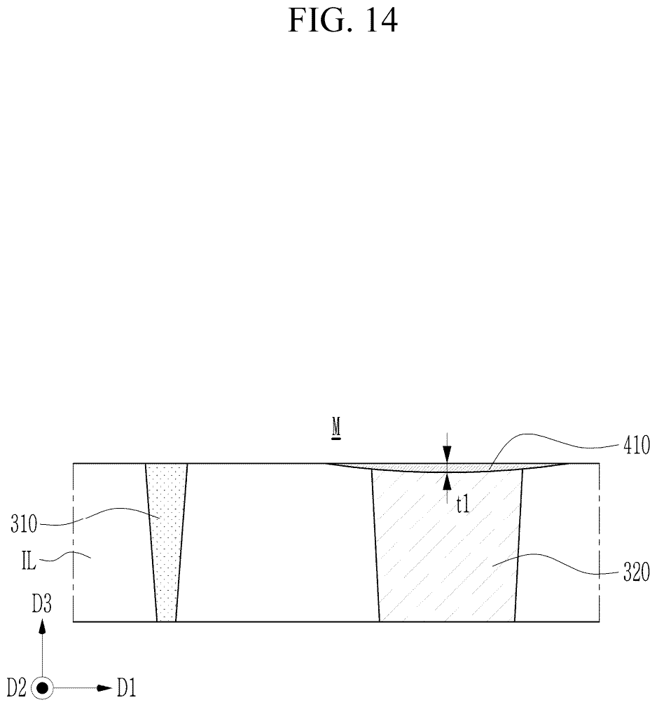

Referring to FIG. 14, a planarization process may be performed to form a contact plug 310. For example, the planarization process may comprise a chemical mechanical polishing (CMP) process.

A portion of the contact plug material layer 310L may be removed by the planarization process. The planarization process may proceed until the top surface of the insulating layer IL is exposed. However, the examples are not limited to this. The planarization process may be continued for a predetermined period of time after the upper surface of the insulating layer IL is exposed. In this case, the thickness of the insulating layer IL in the third direction D3 may be reduced after the planarization process.

According to embodiments, as described above, since the upper surface of the through via 320 is formed at a lower level than the upper surface of the adjacent insulating layer IL, the liner 410 may be formed in a curved shape according to the concave region where the upper surface of the through via 320 is located, and the liner 410 formed in this way may remain in the upper concave region of the through via 320 even after the planarization process is performed. In other words, since the upper surface of the through via 320 is formed at a lower position than the upper surface of the adjacent insulating layer IL, the concave region may not directly contact the polishing surface during the planarization process. Due to this, a portion of the liner 410 located within the concave region may remain without being removed.

For example, the remaining liner 410 may have a first thickness t1 in a direction perpendicular to the upper surface of the substrate 100. Here, the first thickness t1 may mean the thickness of the thickest part of the liner 410.

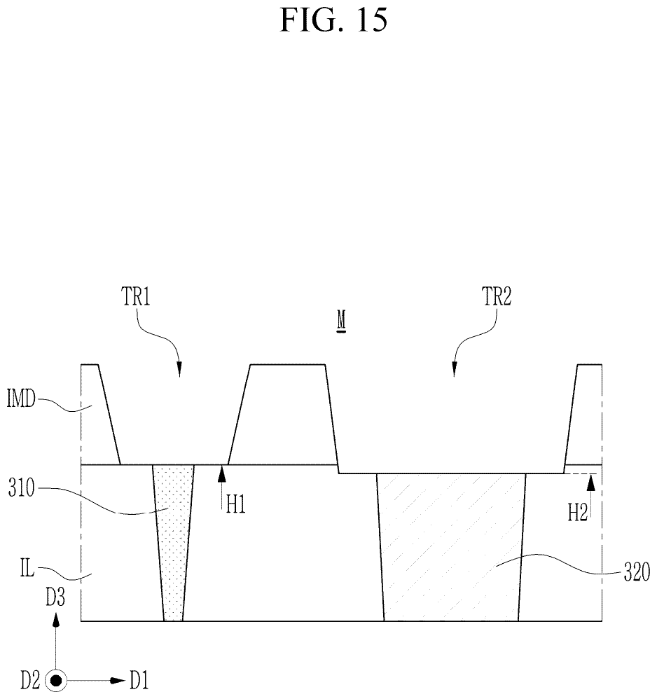

Referring to FIG. 15, a interconnect insulating layer IMD may be formed on a contact plug 310, a liner 410, and an insulating layer IL. The interconnect insulating layer IMD may cover the upper surface of the contact plug 310, the liner 410, and the upper surface of the insulating layer IL.

According to embodiments, the wiring trenches TR1 and TR2 may be formed by patterning the interconnect insulating layer IMD. The interconnect insulating layer IMD may comprise an insulating material.

For example, a photoresist layer may be formed on an insulating layer IL, and a photolithography process may be performed on the photoresist layer to form a photoresist pattern defining an region where a plurality of signal wirings 330 to be described later are to be formed. Next, an etching process is performed using the photoresist pattern as an etching mask to pattern the interconnect insulating layer IMD to form wiring trenches TR1 and TR2.

Specifically, by patterning the interconnect insulating layer IMD, a first wiring trench TR1 that vertically overlaps with the contact plug 310 and a second wiring trench TR2 that vertically overlaps with the through via 320 may be formed.

In embodiments, the etching process may proceed until the upper surfaces of the contact plug 310 and the through via 320 are exposed. At this time, as described above, the liner 410 remains in the upper concave region of the through via 320, so that the lower surface of the second wiring trench TR2 may be formed at a deeper position than the lower surface of the first wiring trench TR1. In other words, the second wiring trench TR2 is formed deeper than the first wiring trench TR1, and the difference in the bottom surface level of the first wiring trench TR1 and the second wiring trench TR2 may correspond to the thickness of the liner 410 remaining on the upper portion of the through via 320, i.e., the first thickness t1.

The lower surface level of the first wiring trench TR1 may be the same as the first level H1 where the upper surface of the contact plug 310 is located, and the lower surface level of the second wiring trench TR2 may be the same as the second level H2 where the upper surface of the through via 320 is located.

In embodiments, the height difference between the first level H1 and the second level H2 may be from about 10 Å to about 500 Å. Specifically, the height difference between the first level H1 and the second level H2 may be about 60 Å to about 120 Å. More specifically, the height difference between the first level H1 and the second level H2 may be about 70 Å to about 100 Å.

Although not explicitly shown, each of the first wiring trench TR1 and the second wiring trench TR2 may have a shape having a width in the first direction D1 and extending in a second direction D2 intersecting the first direction D1. The second direction D2, like the first direction D1, may be parallel to the upper surface of the substrate 100 and may be perpendicular to the first direction D1. The bottom surface of the first wiring trench TR1 may be formed of a contact plug 310 and an upper surface of an insulating layer IL, and the bottom surface of the second wiring trench TR2 may be formed of a through via 320 and an upper surface of an insulating layer IL. The sidewalls of each of the first wiring trench TR1 and the second wiring trench TR2 may be formed of a interconnect insulating layer IMD. The width of each of the first wiring trench TR1 and the second wiring trench TR2 along the first direction D1 may gradually decrease as it approaches the upper surface of the contact plug 310 and the upper surface of the through via 320.

Afterwards, the photoresist pattern may be removed.

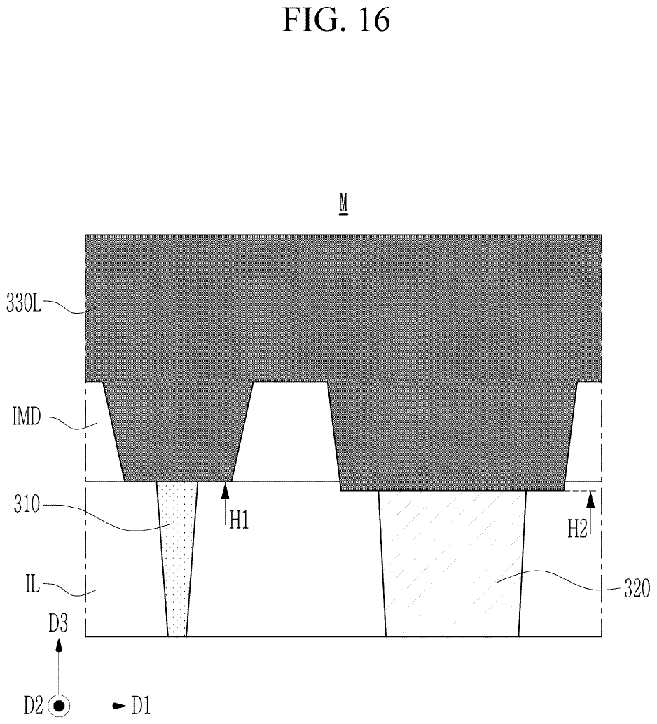

Referring to FIG. 16, a signal wiring material layer 330L may be formed within the wiring trenches TR1 and TR2 and on the upper surface of the interconnect insulating layer IMD. The signal wiring material layer 330L may fill the interior of the wiring trenches TR1 and TR2. The signal wiring material layer 330L may cover the upper surface of the contact plug 310 and the through via 320, the upper surface of the insulating layer IL, and the inner surface of the interconnect insulating layer IMD within the wiring trenches TR1 and TR2. The signal wiring material layer 330L may cover the upper surface of the interconnect insulating layer IMD.

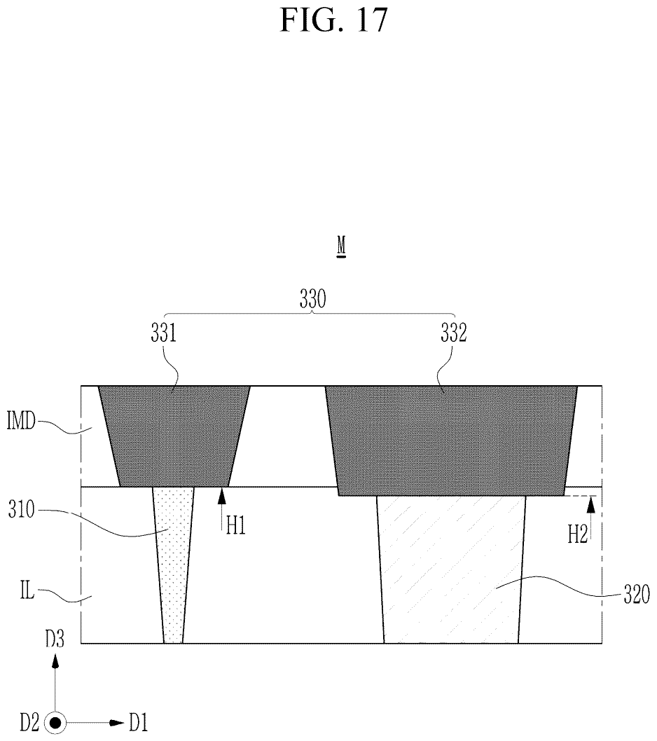

Referring to FIG. 17, signal wiring 330 may be formed by performing a planarization process. A portion of the signal wiring material layer 330L may be removed by the planarization process. The planarization process may proceed until the top surface of the interconnect insulating layer IMD is exposed. Accordingly, signal wiring 330 may be formed separately within the wiring trenches TR1 and TR2. For example, a first signal wiring 331 may be formed in a first wiring trench TR1, and a second signal wiring 332 may be formed in a second wiring trench TR2. The first signal wiring 331 may be connected to a contact plug 310, and the second signal wiring 332 may be connected to a through via 320.

As described above, since the lower surface of the second wiring trench TR2 is formed at a deeper position than the lower surface of the first wiring trench TR1, the lower surface level of the second signal wiring 332 may be lower than the lower surface level of the first signal wiring 331.

The lower surface level of the first signal wiring 331 may be the same as the first level H1 where the upper surface of the contact plug 310 is located, and the lower surface level of the second signal wiring 332 may be the same as the second level H2 where the upper surface of the through via 320 is located.

In embodiments, the height difference between the first level H1 and the second level H2 may be from about 10 Å to about 500 Å. Specifically, the height difference between the first level H1 and the second level H2 may be about 60 Å to about 120 A. More specifically, the height difference between the first level H1 and the second level H2 may be about 70 Å to about 100 Å.

The sides of the signal wiring 330 may be covered by a interconnect insulating layer IMD. An interconnect insulating layer IMD may be positioned between a first signal wiring 331 and a second signal wiring 332 spaced apart in a first direction D1.

As described above, in the semiconductor device manufacturing method according to the present disclosure, by first forming the through via 320 and then forming the contact plug 310, exposure of the contact plug 310 that may occur during the planarization process of the through via 320 may be prevented. Accordingly, galvanic corrosion caused by simultaneous exposure of the through via 320 and the contact plug 310 may be effectively suppressed.

In addition, as described above, in the semiconductor device manufacturing method according to the present disclosure, since the formation time of the contact plug 310 is changed to after the formation of the through via 320, the dishing phenomenon in the contact plug 310 planarization process may be minimized. This is because the horizontal width of the contact plug 310 is smaller than the horizontal width of the through via 320, and as a result, the probability that Cu comprised in the through via 320 and W comprised in the contact plug 310 are exposed on the same plane may be reduced.

In addition, as described above, in the semiconductor device manufacturing method according to the present disclosure, by forming the contact plug 310 after forming the through via 320, the generation of unnecessary Cu residue around the contact plug 310 may be suppressed, thereby reducing defects.

According to embodiments, by forming the contact plug 310 after forming the through via 320, the SIN deposition process before forming the through via 320 after forming the contact plug 310 may be omitted, compared to the conventional technique of forming the through via 320 after forming the contact plug 310, so that the manufacturing cost may be reduced due to a reduction in the number of processes.

According to embodiments, a method of manufacturing a semiconductor device may comprise forming an insulating layer covering a semiconductor element positioned on a substrate, forming a through via hole by etching the insulating layer, depositing a through via material layer on an inner surface of the through via hole and an upper surface of the insulating layer, forming a through via by performing a planarization process, forming a liner on the upper surface of the through via and the upper surface of the insulating layer, forming a hard mask pattern on the liner over the upper surface of the through via, removing the exposed liner using the hard mask pattern as an etch mask, forming a contact plug hole by etching the insulating layer, depositing a contact plug material layer on the inner surface of the contact plug hole, the insulating layer, and the upper surface of the liner, and forming a contact plug by performing a planarization process.

According to embodiments, in the method of manufacturing the semiconductor device, a horizontal width of the through via hole may be greater than a horizontal width of the contact plug hole.

According to embodiments, the method of manufacturing the semiconductor device may comprise forming a wiring insulating layer covering the contact plug and the through via, forming a plurality of wiring trenches by etching the wiring insulating layer to expose the upper surface of the contact plug and the upper surface of the through via, and forming a plurality of signal wirings in the plurality of wiring trenches.

According to embodiments, in the method of manufacturing the semiconductor device, the plurality of signal wirings may comprise a first signal wiring connected to the contact plug and a second signal wiring connected to the through via.

According to embodiments, in the method of manufacturing the semiconductor device, a lower surface of the first signal wiring may be in contact with the upper surface of the contact plug, and a lower surface of the second signal wiring may be in contact with the upper surface of the through via.

According to embodiments, in the method of manufacturing the semiconductor device, the upper surface of the contact plug may be located at a different level from the upper surface of the through via.

According to embodiments, in the method of manufacturing the semiconductor device, the upper surface of the contact plug may be located at a first level, and the upper surface of the through via may be located at a second level lower than the first level.

According to embodiments, in the method of manufacturing the semiconductor device, the first level may be 60 Å to 120 Å higher than the second level.

According to embodiments, in the method of manufacturing the semiconductor device, the contact plug material layer may comprise at least one of tungsten, copper, aluminum, tantalum, titanium, or a combination thereof.

According to embodiments, in the method of manufacturing the semiconductor device, the through via material layer may comprise at least one of copper, tungsten, aluminum, or a combination thereof.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device comprising:
a substrate;
a semiconductor element on the substrate;
an insulating layer on the semiconductor element;
a wiring structure on the insulating layer, the wiring structure comprising a first wiring and a second wiring;
a contact plug passing through the insulating layer to connect the semiconductor element and the first wiring; and
a through via passing through the substrate and the insulating layer and connected to the second wiring,
wherein an upper surface of the contact plug is located at a different level from a level of an upper surface of the through via.

2. The semiconductor device of claim 1,
wherein the upper surface of the contact plug is at a first level, and the upper surface of the through via is at a second level lower than the first level.

3. The semiconductor device of claim 2,
wherein the first level is 60 Å to 120 Å higher than the second level.

4. The semiconductor device of claim 1,
wherein a first width of the contact plug in a horizontal direction is less than a second width of the through via in the horizontal direction.

5. The semiconductor device of claim 1,
wherein the contact plug comprises at least one of tungsten, copper, aluminum, tantalum, titanium, or a combination thereof.

6. The semiconductor device of claim 1,
wherein the through via comprises at least one of copper, tungsten, aluminum, or a combination thereof.

7. A semiconductor device comprising:
a base die comprising a plurality of conductive lines;
a plurality of memory dies stacked on the base die; and
a molding material covering the base die and the plurality of memory dies;
wherein each of the plurality of memory dies comprises:
a substrate;
a semiconductor element on the substrate;
an insulating layer on the semiconductor element;
a wiring structure on the insulating layer, the wiring structure comprising a first wiring and a second wiring;
a contact plug passing through the insulating layer to connect the semiconductor element and the first wiring; and
a through via passing through the substrate and the insulating layer and connected to the second wiring,
wherein an upper surface of the contact plug is located at a different level from a level of an upper surface of the through via.

8. The semiconductor device of claim 7,
wherein the upper surface of the contact plug is at a first level, and the upper surface of the through via is at a second level lower than the first level.

9. The semiconductor device of claim 8,
wherein the first level is 60 Å to 120 Å higher than the second level.

10. The semiconductor device of claim 7,
wherein a first width of the contact plug in a horizontal direction is less than a second width of the through via in the horizontal direction.

11. The semiconductor device of claim 7,
wherein the contact plug comprises at least one of tungsten, copper, aluminum, tantalum, titanium, or a combination thereof.

12. The semiconductor device of claim 7,
wherein the through via comprises at least one of copper, tungsten, aluminum, or a combination thereof.

13. The semiconductor device of claim 8,
wherein the base die is a logic die and each of the plurality of memory dies is a DRAM die.

14. A semiconductor device comprising:
a base die;
a memory stack on the base die; and
a molding material encapsulating the memory stack on the base die,
wherein the memory stack comprises a plurality of memory dies and a plurality of interconnection structures,
wherein the plurality of memory dies comprise a first memory die disposed closest to the base die and a second memory die disposed on the first memory die,
wherein the plurality of interconnection structures comprise a first interconnection structure connecting the base die and the first memory die, and a second interconnection structure connecting the first memory die and the second memory die,
wherein the first memory die and the second memory die each comprise:
a semiconductor element on a substrate;
an insulating layer on the semiconductor element;
a wiring structure on the insulating layer, the wiring structure comprising a first wiring and a second wiring;
a contact plug passing through the insulating layer to connect the semiconductor element and the first wiring; and
a through via passing through the substrate and the insulating layer and connected to the second wiring,
wherein an upper surface of the contact plug is located at a different level from a level of an upper surface of the through via.

15. The semiconductor device of claim 14,
wherein the upper surface of the contact plug is at a first level, and the upper surface of the through via is at a second level lower than the first level.

16. The semiconductor device of claim 15,
wherein the first level is 60 Å to 120 Å higher than the second level.

17. The semiconductor device of claim 14,
wherein a first width of the contact plug in a horizontal direction is less than a second width of the through via in the horizontal direction.

18. The semiconductor device of claim 14,
wherein the base die is a logic die and the plurality of memory dies are DRAM dies.

19. The semiconductor device of claim 14,
wherein each of the plurality of interconnection structures comprises:
a plurality of first bonding pads;
a first silicon insulating layer insulating the plurality of first bonding pads;
a plurality of second bonding pads on the plurality of first bonding pads and directly bonded to the plurality of first bonding pads; and
a second silicon insulating layer on the first silicon insulating layer and directly bonded to the first silicon insulating layer.

20. The semiconductor device of claim 14,
wherein each of the plurality of interconnection structures comprises:
a plurality of microbumps; and
a non-conductive film (NCF) insulating the plurality of microbumps from one another.
